(19) United States
(12) Patent Application Publication
(10) Pub. No.: US 2005/0063213 A1
(43) Pub. Date: Mar. 24, 2005

(54) Signal margin test mode for FeRAM with ferroelectric reference capacitor

(76) Inventors: Michael Jacob, Kanagawa-ken (JP); Thomas Roehr, Kanagawa-ken (JP); Hans-Oliver Joachim, Kanagawa-ken (JP)

Correspondence Address: FISH & RICHARDSON, PC, 12390 EL CAMINO REAL, SAN DIEGO, CA, 92130-2081, US

(21) Appl. No.: 10/665,402

(22) Filed: Sep. 18, 2003

(51) Int. Cl. G11C 11/22

(52) U.S. Cl. 365/145

(57) ABSTRACT

The present invention provides a semiconductor memory test mode configuration. A first capacitor stores digital data and connects a cell plate line to a first bit-line through a first select transistor. The first select transistor is activated through a connection to a word line. At least one reference capacitor provides a reference voltage to a reference bit-line. A sense amplifier is connected to the first and reference bit-lines and measures a differential read signal on the first and reference bit-lines. A charge path reduces the differential read signal to determine the signal margin of the semiconductor memory.

### FIELD OF THE INVENTION

The present invention relates to the implementation of circuits for testing signal margin in memory cells.

### BACKGROUND OF THE INVENTION

In semiconductor memories, reliability issues have become more complicated with increasing memory sizes, smaller feature sizes and lower operating voltages. It has become more important to understand the cell signal sensing operation, the signal of memory cells and the limiting factors.

One particularly important characteristic in reliability determinations of semiconductor memories is the signal margin. The signal margin is a measure of the zero-versus-one signal measured by the sense amplifier. It is particularly useful to be able to measure the signal margin at product level. The results of product-level signal margin tests can be used to optimize reliability as well as the sense amplifier design and the bit-line architecture to optimize dynamic memory cell readout. Moreover, a product level test sequence for signal margin can help ensure full product functionality over the entire component lifetime taking all aging effects into account.

A design challenge for 1T1C (one-transistor one-capacitor per memory cell) FeRAM (Ferroelectric Random Access Memory) devices is the establishment of the reference voltage, which is complicated by the ferroelectric capacitor being a non-linear, hysteretic circuit element. Approaches include averaging the charge of one switching and one non-switching ferroelectric capacitor, using a non-switched ferroelectric capacitor, using a “dummy” reference capacitor (e.g. MOS capacitor), or using a direct reference voltage supply. All of these solutions have advantages and disadvantages.

Use of “dummy” reference capacitors or direct reference voltage sources has the advantage of enabling the implementation of a 1T1C signal margin test mode by variation of the “dummy” plate voltage or by variation of the direct reference voltage. However, designs using the “dummy” reference capacitors or direct reference voltage sources require large signal margins. This is because the temperature behavior of the “dummy” reference capacitors and direct reference voltage sources, along with the response to changes or deviations in the manufacturing process, may be different from those of the ferroelectric capacitors of the memory cell.

The use of ferroelectric reference capacitors has the advantage of being “self-adjusted” to manufacturing deviations and temperature changes, but implementation of a test mode for signal margin tests is more complicated than for the other solutions. Sweeping the power used for the ferroelectric reference 10 capacitors does not correctly measure the signal margin due to the fluctuation of the ferroelectric capacitors.

FIG. 1 shows a general memory chip 102 configuration for providing a reference voltage for an FeRAM memory cell 101 having a 1T1C configuration. The 1T1C configuration utilizes one transistor and one capacitor per bit. The read signal of a ferroelectric cell capacitor on a bit-line BL 103 of a FeRAM memory cell 101 is compared to a reference signal on a reference bit-line BLr 107 generated by a reference voltage generation circuit 105. A differential read signal on the bit-line pair 103, 107 is evaluated by a connected sense amplifier 109.

FIG. 2 includes the details of a prior-art memory chip circuit 201 having a reference circuit 200 for generating the reference voltage for the configuration of FIG. 1. There is a single non-switched reference capacitor, indicated by Qnsw which is somewhat larager than the memory cell capacitors and which outputs signals between “0” and “1” (see the paper by T. Sumi et al., ISSCC Digest of Technical Papers, p. 268, 1994 for additional details).

FIG. 3 shows the details of another prior-art FeRAM circuit 301 including the circuit for generating the reference voltage 105 and the 1T1C memory cell 101 of FIG. 1. Also shown is a second 1T1C cell 303. During typical use there will be multiple memory cells connected in parallel to a bit-line, each storing a bit of information. The reference voltage from the circuit 105, along with the outputs from the outputs from the memory cells 101 and 303, are fed to the sense amplifier 109 and also a sense amplifier 305. Once again, the reference voltage is created by averaging the charges Qsw and Qnsw of ferroelectric capacitors (see the paper by D. Jung et al., IEDM Digest of Technical Papers, p. 279, 1999 for additional details). Here the reference capacitor 307 has the charge Qsw (switching) and the reference capacitor 309 has the charge Qnsw (non-switching).

FIG. 4 shows the timing for the reference voltage circuit of FIG. 3. The reference write line signal WLr is applied to gates of transistors 311 and 313 to provide a path between the ferroelectric reference capacitors 307, 309 and the reference bit-lines BLr0 and BLr1. At t0 the reference plate line (with potential PLr) is activated. The potential PLr charges the reference bit-lines BLr0 and BLr1 through the ferroelectric reference capacitors Qsw and Qnsw as shown by the plot of the potential on BLr0/1. Due to differences between the polarization states of the ferroelectric reference capacitors 307, 309 the reference bit-lines charge to different potentials during the time the reference word line signal WLr is applied. At time t1 the reference write line signal WLr is deactivated and the signal BLreq (bit-line reference equal) is applied to a transistor 315 to electrically connect the reference bit-lines BLr0 and BLr1 through the transistor 315 thereby equalizing the potential of the two bit-lines by averaging their potentials. At time t2 the signal BLreq is deactivated, the signal WBr (write back reference) is applied to the gates of transistors 317, 319 and the sense amplifier 109 is enabled. During the time the sense amplifier 109 is activated, the timing is related to the timing of the 1T1C FeRAM cell 101. At time t3 the reference plate line (with potential PLr) is deactivated and the signal WBr0 is applied to the transistor 317 to begin write back to the switched ferroelectric reference capacitor 307. Finally at time t4 write back ends by turning off the signals WBr0 and WBr.

It would be desirable to provide a signal margin test mode for a FeRAM having a ferroelectric reference capacitor as in the circuit of FIG. 3. It would additionally be desirable to provide a circuit with a test mode section for facilitating a worst case product test sequence for signal margin determined from a differential read signal on a bit-line supplied by a FeRAM cell having a 1T1C configuration and a reference line potential generated using a ferroelectric capacitor.

### SUMMARY OF THE INVENTION

The present invention provides a semiconductor memory test mode configuration. A first capacitor stores digital data and connects a cell plate line to a first bit-line through a first select transistor. The first select transistor is activated through a connection to a word line. At least one reference capacitor provides a reference voltage to a reference bit-line. A sense amplifier is connected to the first and reference bit-lines and measures a differential read signal on the first and reference bit-lines. A charge path reduces the differential read signal to determine the signal margin of the semiconductor memory.

The present invention also includes a method for testing the signal margin of a semiconductor memory. The method includes reducing the difference between the amount of charge on a reference bit-line and on a first bit-line. A sense amplifier is connected to the first and second bit-lines and is activated thereby boosting read signals on the first bit-line representing digital data read from a capacitor and boosting read signals on the reference bit-line. A reduced differential read signal on the first and reference bit-lines due to the changed amount of charge on the bit-lines is determined.

### BRIEF DESCRIPTION OF THE FIGURES

Further preferred features of the invention will now be described for the sake of example only with reference to the following figures, in which:

FIG. 1 shows a prior-art memory chip circuit configuration for providing a reference voltage for an FeRAM memory cell having a 1T1C configuration.

FIG. 2 includes the details of a prior-art memory chip circuit 201 for generating the reference voltage for the configuration of FIG. 1

FIG. 3 shows the details of another prior-art FeRAM circuit including a circuit for generating the reference voltage and a 1T1C memory cell of FIG. 1.

FIG. 4 shows the timing for the reference voltage circuit of FIG. 3.

FIG. 5 shows a circuit schematic diagram for using different pre-charge levels for the bit-lines to add a signal margin test mode to memory chip circuit of FIG. 1.

FIG. 6 shows bit-line signals for the circuit of FIG. 5 for the case where a reference bit-line BLr is expected to have a signal level lower than the potential of the bit-line BL.

FIG. 7 shows bit-line signals for the circuit of FIG. 5 for the case where a reference bit-line BLr is expected to have a signal level higher than the potential of the bit-line BL.

FIGS. 8 and 9 show circuit schematic diagrams for embodiments using resistive elements for adding a signal margin test mode to memory chip circuit of FIG. 1.

FIG. 10 shows the reference bit-line signals for embodiment of the circuit of FIG. 8.

FIG. 11 shows the signals on a bit-line BL and reference bit-line BLr of the circuit of FIG. 8.

FIGS. 12 and 13 show signals on a bit-line BL and reference bit-line BLr of the circuit of FIG. 9.

FIG. 14 shows a circuit schematic diagram for using a defined charge exchange between a bit-line BL and reference bit-line BLr for adding a signal margin test mode to memory chip circuit of FIG. 1.

FIGS. 15 and 16 show signals on the bit-line BL and reference bit-line BLr of the circuit of FIG. 14.

FIG. 17 shows a circuit schematic diagram for using a defined charge/discharge of a bit-line BL and reference bit-line BLr for adding a signal margin test mode to memory chip circuit of FIG. 1.

FIG. 18 shows signals on the bit-line BL and reference bit-line BLr of the circuit of FIG. 17.

FIG. 19 illustrates general embodiment of the present invention.

### DETAILED DESCRIPTION OF THE EMBODIMENTS

The present invention provides a signal margin test mode for FeRAM memory chips configured to use reference voltages generated by ferroelectric reference capacitors. A general embodiment of the present invention is illustrated in FIG. 19. A signal margin test mode section 104 adds and/or removes charge Q, Qr from the bit-line 103 and/or reference bit-line 107, respectively. The charge on the bit-line with the higher read signal is decreased and/or the charge on the bit-line with the lower read signal is increased resulting in a decreased signal on this bit-lines. As a result, the differential read signal, i.e. the difference between the two bit-line signals, is decreased accordingly, which tightens the margin for a save operation of the chip (the worst case test condition) for measuring signal margin.

### First Embodiment

### Using Different Pre-Charge Levels for the Bit-Lines

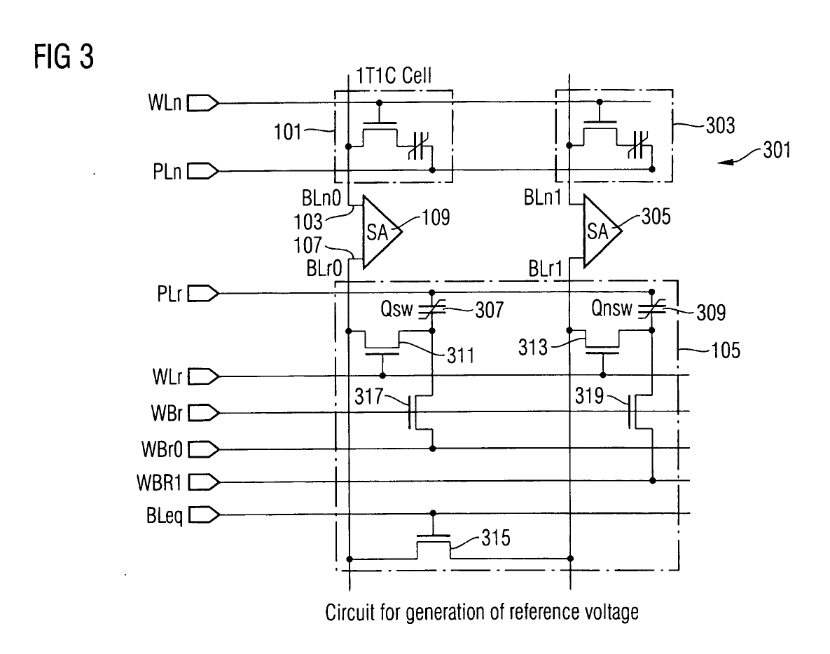

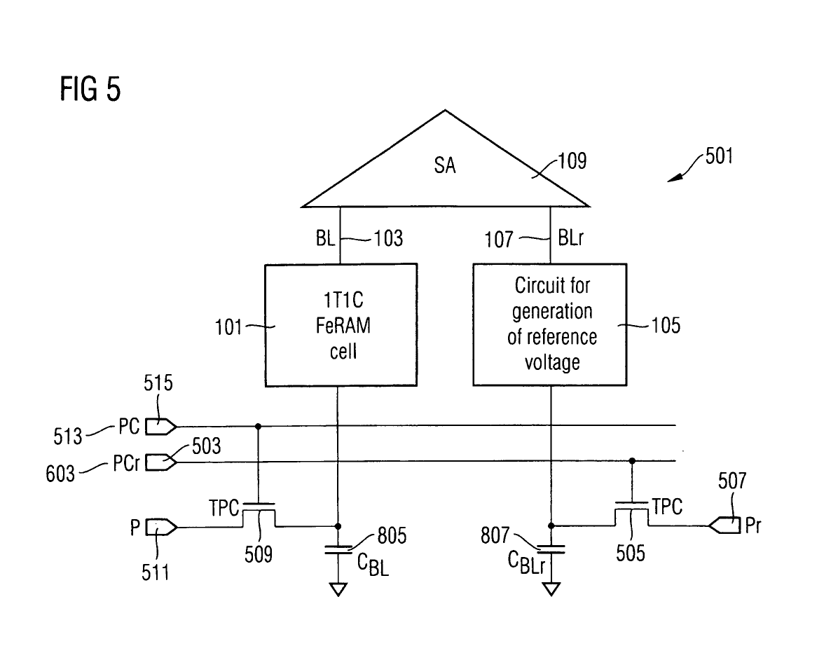

FIG. 5 shows a circuit schematic diagram for adding a signal margin test mode to a memory chip 501 including the 1T1C FeRAM memory cell 101 and the circuit for the generation of a reference voltage 105, both fed into the sense amplifier 109. In this example, it is assumed that the circuit 105 of FIG. 3 is used as the circuit for the generation of the reference voltage 105 of FIG. 5, however, other circuits can be substituted for use as the circuit 105.

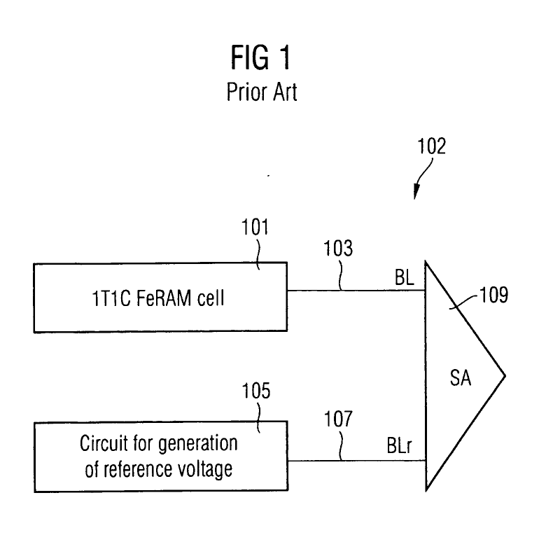

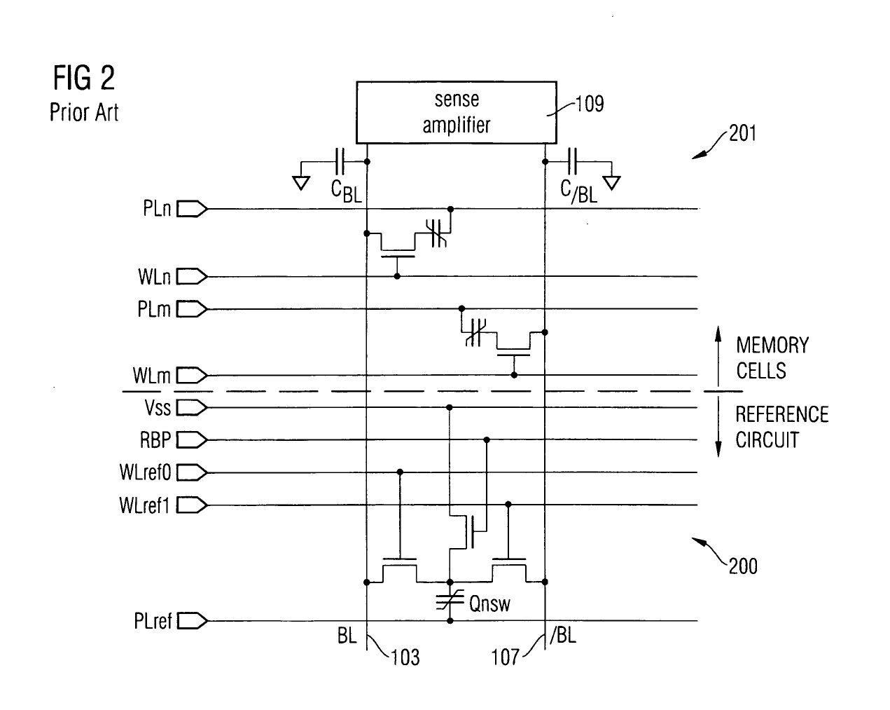

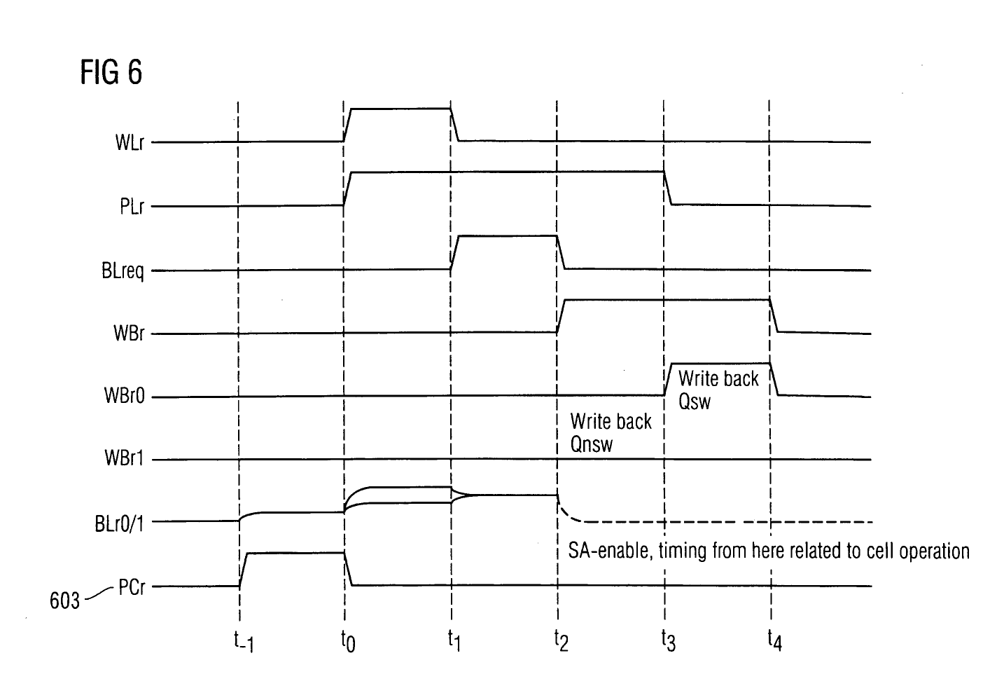

The circuit 501 of FIG. 5 provides a test mode circuit for testing for signal margin. In order to test the memory chip 501, first data is written into the memory cell 101 and afterwards the data is read and compared to the expected (i.e. written) data. Thus, during testing it is known which line, BL 103 or BLr 107, should have a lower and which should have a higher signal. The signal margin can be tested by selectively reducing the difference between a “0” signal on one bit-line and a “1” signal on the other bit-line. The bit-line that is expected to have the higher signal during testing is pre-charged to a normal level as in the prior art memory cell of FIG. 1. However, the bit-line which is expected to have the lower signal during testing is pre-charged to a level which is higher than the normal pre-charge level of the higher signal level bit-line. The result of this test mode is a reduced differential read signal (i.e. the difference between the two bit-line signals) on the bit-lines following the activation of a plate line PLn (shown in FIG. 3), which tightens the margin for a save operation of the memory chip (the worst case test condition). The amount of “signal margin” can be controlled by the level of the signals Pr 507 and P 511 fed into the transistors TPC 507, 509. The amount of “signal margin” can also be controlled by the time window during which the transistors TPC 507, 509 are switched on, i.e. between t₋₁ and t0 in FIG. 6.

FIG. 6 shows the bit-line signals for the case where the reference bit-line BLr 107 is expected to have a signal level Pr (Potential reference) 507 lower than the potential of the bit-line BL 103. The test mode of the present invention is activated at time t₋₁ by applying a test mode signal potential PCr (Pre-Charge reference) 603 (see FIG. 6) to the gate of a first transistor TPC (Transistor Pre-charge) 505 through an electrical connection 503. The potential PCr 603 activates the transistor TPC 505 to pre-charge the reference bit-line BLr 107 to the level Pr 507 which is higher than its normal pre-charge level. The other bit-line BL 103, for which the higher signal level P 511 is expected, is pre-charged to a signal level P 511 that is the same as its normal level. The bit-line BL 103 can be charged in the same way as in the normal read operation, or can be charged via a second transistor TPC 509 which is activated by applying a test mode signal potential PC 513 to the gate of the transistor TPC 509 through an electrical connection 515.

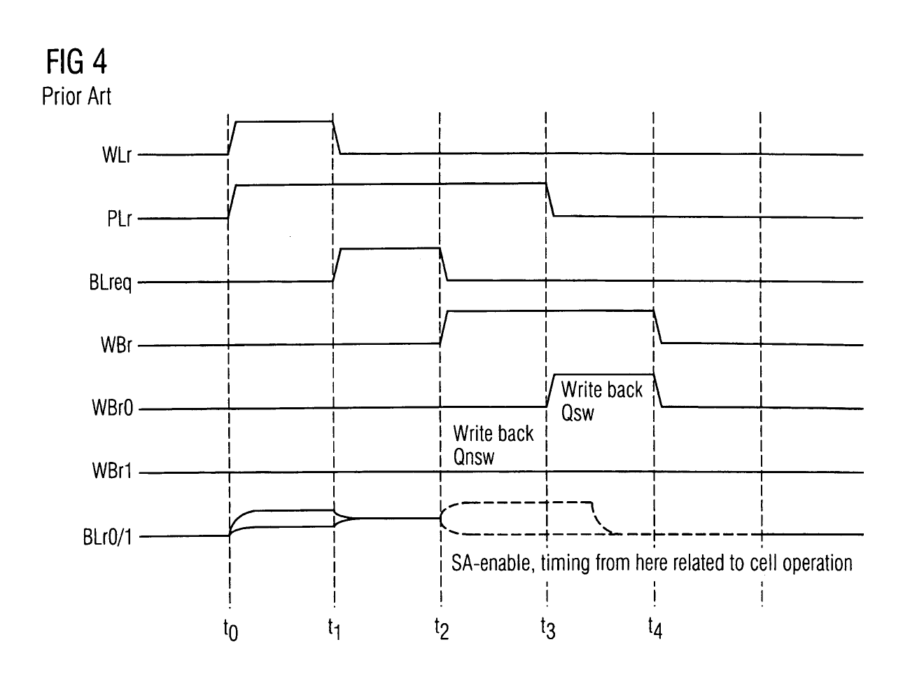

After the pre-charging of the reference bit-line BLr 107 to the level Pr 507, the potential PCr 603 is turned off at time t0 and the steps of time t0 to t4 are performed as in FIG. 4. As can be seen from a comparison of the reference bit-line signals BLr0/1 of FIG. 6 with those of FIG. 4, the reference bit-line signal has been increased by the pre-charging using the potential Pr 507. In this example the pre-charging is shown during the time interval t₋₁ to t0, however, the precharging can be performed during other time intervals prior to activation of the sense amplifier 109 at t2.

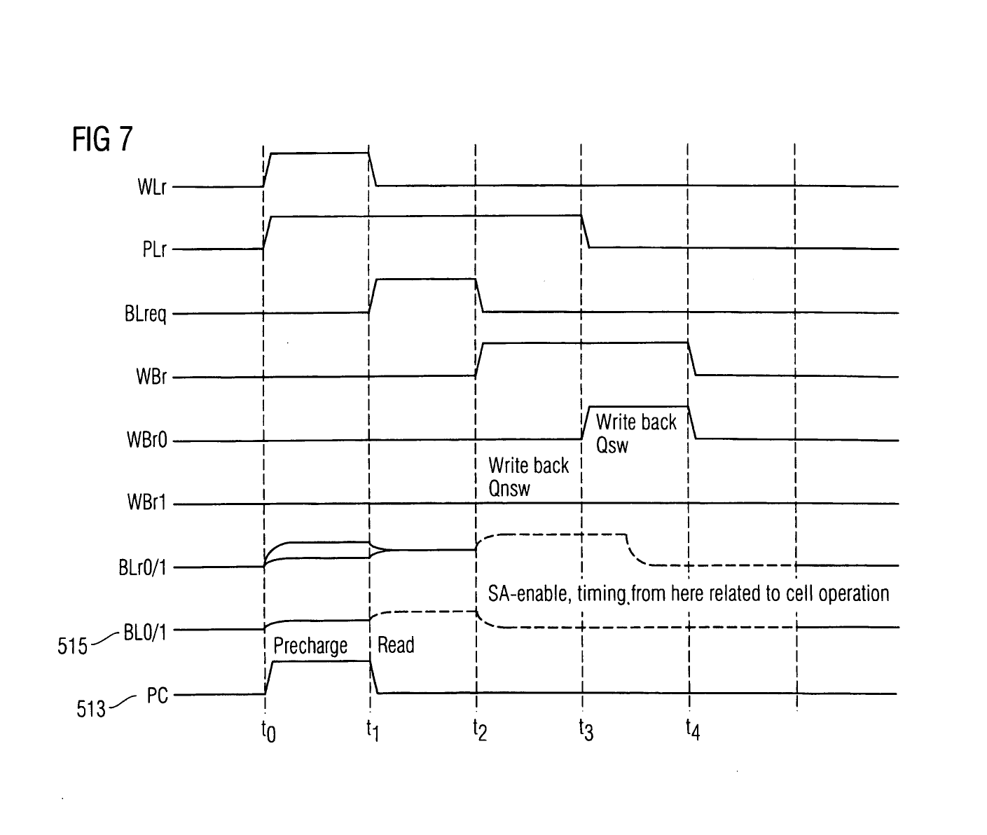

FIG. 7 shows the signals for the case where the reference bit-line BLr 107 is expected to have a signal level Pr (Potential reference) 507 higher than the potential of the bit-line BL 103. The test mode of is activated by applying the test mode signal potential PC 513 (see FIG. 7) to the gate of the transistor TPC 509 through an electrical connection 515. The potential PC 513 activates the transistor TPC 509 to pre-charge the bit-line BL 103 to the level P 511 which is higher than its normal pre-charge level. The reference bit-line BLr 107, for which the higher signal level Pr 507 is expected, is pre-charged to a signal level Pr 507 that is the same as its normal level. The reference bit-line BLr 107 can be charged in the same way as in the normal read operation, or can be charged via a second transistor TPC 507 which is activated by applying a test mode signal potential PCr 603 to the gate of the transistor TPC 505 through an electrical connection 503. In this example the pre-charging is shown during the time interval t0 to t1, however, the precharging can be performed from t₋₁ to t0 as in the example of FIG. 6, or during other time intervals prior to activation of the sense amplifier 109 at t2. As can be seen from bit-line signal BL0/1 515, the potential is increased by the pre-charging using the potential PC 513.

The signal inputs PC 513 and PCr 603 are kept at non-active (wherein the transistors TPC 505 and TPC 509 are off) during normal operation and the memory chip circuit is electrically similar to the memory chip circuit shown in FIG. 1.

The following steps illustrate a procedure for testing the analog value of the signal margin of the memory chip circuit 501 of FIG. 5 for the embodiment of FIG. 6 wherein the reference bit-line BLr 107 is expected to have a signal level Pr 507 lower than the potential of the bit-line BL 103:
1. Write data to and then read data from the memory cell 101 in normal operation (without activating the transistors TPC 505, 509). If the differential read signal is too small, then a comparison of the read data with the write data fails, thereby indicating that the circuit has no signal margin. If the differential read signal is sufficiently large then step 2 is performed.
2. Write data to and then read data from the memory cell 101 with the pre-charge level of Pr 507 set to a value slightly higher than the normal pre-charge level P 511 to pre-charge the bit-line reference bit-line BLr 107 to a level PCr 603 which is higher than the signal level on the bit-line BL 103. If the differential read signal is too small, then a comparison of the read data with the write data fails, thereby indicating that the circuit has no signal margin. If the differential read signal is sufficiently large then step 3 is performed.
3. Write data to and then read data from the memory cell 501 with the level of Pr 507 of the transistor TPC 505 set to a slightly larger value corresponding to first signal margin (SM1) to pre-charge the reference bit-line BLr 107 to a level PCr 603 which is higher than the signal level on the bit-line BL 103. If the differential read signal is too small, then a comparison of the read data with the write data fails, thereby indicating that the circuit has a signal margin corresponding to SM0. If the differential read signal is sufficiently large then step 4 is performed.
4. Write data to and then read data from the memory cell with the level of Pr 507 of the transistor TPC 505 set to an even larger value corresponding to second signal margin (SM2) to reference bit-line BLr 107 to a level PCr 603 which is higher than the signal level on the bit-line BL 103. If the differential read signal is too small, then a comparison of the read data with the write data fails, thereby indicating that the circuit has a signal margin corresponding to SM1. If the differential read signal is sufficiently large then the test is continued until the failure of the comparison.

In another embodiment the pre-charge level of the bit-line for which the higher signal is expected is reduced, and the pre-charge level of the other bit-line is kept at its normal level.

In another embodiment the pre-charge levels for both the bit-line BL 103 and the reference bit-line BLr 107 are varied simultaneously so that the pre-charge level of the bit-line for which the higher signal is expected is reduced, while the pre-charge level of the bit-line for which the lower level is expected is increased.

In one embodiment the potentials P 511 and Pr 507 are generated internally by the memory chip 501. In another embodiment the potentials P 511 and Pr 507 are generated externally to the chip.

During read out, differences between the voltages on the ferroelectric reference capacitors 307, 309 and the ferroelectric capacitors of the memory cells 101, 103 can arise due to the two different pre-charge levels. The present invention can overcome these differences in voltages by adjusting the voltages on the word lines WLr, WLn and/or the plate lines PLr, PLn and/or by adjusting the read time (t0 to t1 in FIG. 6) or in other ways.

### Second Embodiment

### Using Resistive Elements

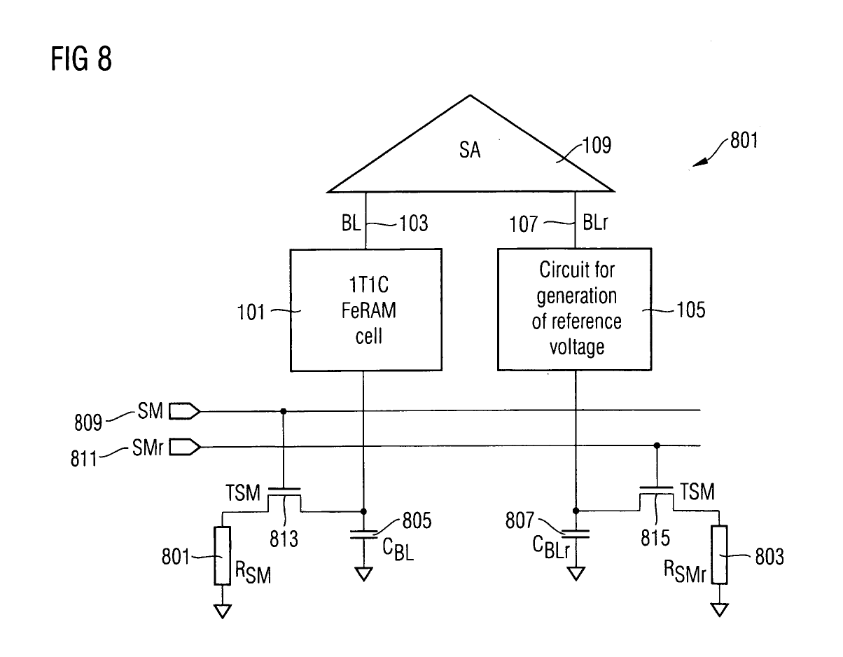

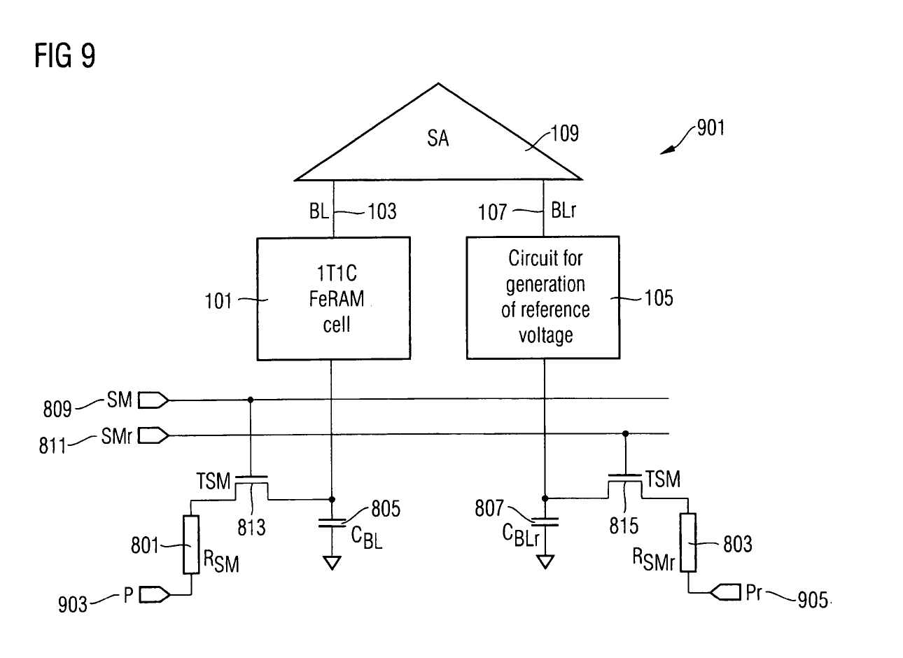

FIGS. 8 and 9 show circuit schematic diagrams of additional embodiments for adding a signal margin test mode to memory chip circuits 801, 901 including the 1T1C FeRAM memory cell 101 and the circuit for the generation of a reference voltage 105, both fed into the sense amplifier 109. In this example, it is also assumed that the circuit 105 of FIG. 3 is used as the circuit for the generation of the reference voltage 105 of FIGS. 8 and 9, however, other circuits can be substituted for use as the circuit 105. The signal margin is tested by using resistive elements to adjust the relative charge levels of BL 103 and BLr 107 to reduce the differential read signal.

Additional resistors RSM 801 and RSMr 803 are connected in parallel to bit-line capacitances CBL 805 and CBLr 807, respectively. The resistors 801, 803 are separately switchable for the bit-lines BL 103 and BLr 107 by separate signals SM 809 or SMr 811 on the transistors TSM 813 and TSM 815. In another embodiment, both of the signal inputs SM 809 and SMr 811 are activated in parallel. The signal inputs SM 809 and SMr 811 are kept at non-active (wherein the transistors TSM 813 and TSM 815 are off) during normal operation and the memory chip circuit is electrically similar to the circuit shown in FIG. 1.

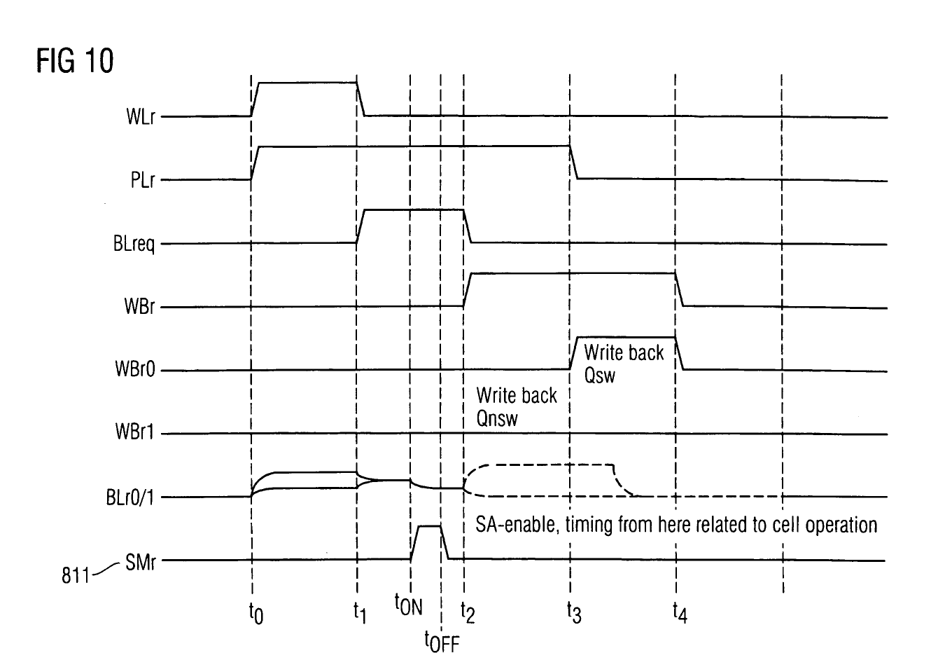

During testing of the embodiment of FIG. 8, one of the signal inputs (or, in another embodiment, both of the signal inputs) SM 809 or SMr 811 can be activated thereby opening a controlled “leakage path” for the bit-line charge via the resistor RSM 801 or 803 to ground, thus decreasing the read voltage on the respective bit-line. The higher signal, which can be on either BL 16 or /BL 16′, is therefore reduced and the difference between the higher and lower bit-line signals becomes smaller for this test. The amount of “signal margin” can be controlled by the time window during which the transistors TSM 815 are switched on, i.e. between t2 and t3 (see FIG. 10).

FIG. 10 shows the reference bit-line signals for the case where the reference bit-line BLr 107 is expected to have a signal level SMr 811 higher than the potential of the bit-line BL 103. The steps t0 to tON are performed as in FIG. 4. The test mode of the present invention is activated at time tON by applying a test mode signal potential SMr 811 (see FIG. 8) to the gate of a first transistor TSM 815. The potential SMr 811 activates the transistor TSM 815 to drain charge from the reference bit-line BLr 107 to lower the voltage on the reference bit-line as shown by the plot of the potential of BLr0/1 from tₒₙ to t_{off} in FIG. 10. The other bit-line BL 103, for which a lower signal level is expected, is pre-charged to a signal level that is the same as its normal level. The bit-line BL 103 can be charged in the same way as in the normal read operation, or can be charged/drained via a second transistor TSM 813 which is activated by applying a test mode signal potential to the gate of the transistor TSM 813.

After the charging of the reference bit-line BLr 107, the potential SMr 811 is turned off at time t_{OFF} and the remaining operations are performed as in is FIG. 4. As can be seen from a comparison of the reference bit-line signals BLr0/1 of FIG. 10 with those of FIG. 4, the reference bit-line signal has been decreased by draining current through the reference resistor RSMr 803. In this example the charging is shown during the time interval t_{ON} to t_{OFF} between times t1 and t2, however, as in the previous examples, the charging can be performed during other time intervals including during the interval between t0 and until the activation of the sense amplifier 109 at t2.

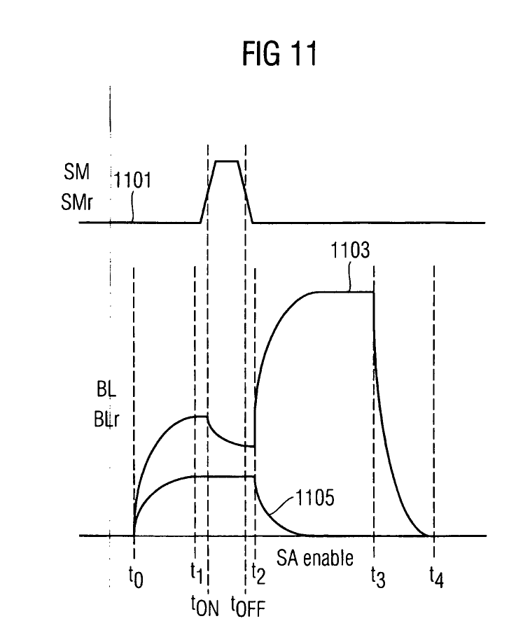

FIG. 11 shows the signals on the bit-line BL 103 and reference bit-line BLr 107 in greater detail. The trace 1101 represents the signals SM 809 or SMr 811 for activating the transistors TSM 813 or 815. The traces 1103 and 1105 represent the signal levels on the bit-lines BL 103 and BLr 107. First, the bit-lines BL 103 and BLr 107 are charged to a certain level (e.g. 0V in the figure). At time t0 the common plate line PLr and the write line WLr are activated and a read signal appears on the bit-lines 103, 107. At time t1 the full read signals are developed on the two bit-lines 103, 107. At time t_{ON}, the signal SMr 811 is activated if the bit-line BLr 107 is expected to have the higher signal, or the signal SM 809 is activated if the bit-line BL 103 is expected to have the higher signal. Activating the signal SMr 811 switches on the transistor TSM 813 while activating the signal SM 809 switches on the transistor TSM 813. At time t_{OFF}, the signal SM 809 or SMr 811 is deactivated again, once again turning off transistors TSM 813 or TSM 815, respectively. There is no limitation for tON and tOFF in this embodiment. In one preferred embodiment, the signal SM 809 is activated at a time tON concurrent with or after the time t1 at which the signals are developed on the bit-lines (tON≧t1). Before or concurrently with the time t2 at which a sense amplifier 109 is turned on, de-charging of the bit-lines is finished and the signal SM 809 is deactivated (tOFF≦t2). In other embodiments, tON can occur before t1 in order to help save access time. Also tOFF can occur after t2.

The charge on the bit-line with the higher read signal is decreased by draining off charge through the resistors RSM 801 or 803, resulting in a decreased signal on this bit-line at t2 when the sense amplifier 109 is activated and the bit-line signals are boosted to the full bit-line voltages. As a result, the differential read signal, i.e. the difference between the two bit-line signals, is decreased accordingly, which tightens the margin for a save operation of the chip (the worst case test condition). In FIG. 11, at t3 the sense amplifier 109 is deactivated and the access cycle ends at t4. The signal margin can be determined by varying the time window during which the transistor TSM 24 is switched on, i.e. between tON and tOFF. For different time windows data is written to and read from the memory cell 101. The actual signal margin is determined from the point wherein the time window becomes narrow enough so that the signal read changes from pass to fail.

One example of the procedure to test for the analog value of the signal margin is illustrated by the following steps:
1. Write data to and then read data from the memory cell in normal operation (without activating the transistors TSM 813 or 815). If the differential read signal is too small, then a comparison of the read data with the write data fails, thereby indicating that the circuit has no signal margin. If the differential read signal is sufficiently large then step 2 is performed.
2. Write data to and then read data from the memory cell with the time window of the transistors 813 or 815 set to a small value signal margin (SM0) to drain some of the charge from the bit-lines. If the differential read signal is too small, then a comparison of the read data with the write data fails, thereby indicating that the circuit has no signal margin. If the differential read signal is sufficiently large then step 3 is performed.
3. Write data to and then read data from the memory cell with the time window of the transistors 813 or 815 set to a slightly larger value corresponding to first signal margin (SM1) to drain some of the charge from the bit-lines. If the differential read signal is too small, then a comparison of the read data with the write data fails, thereby indicating that the circuit has a signal margin corresponding to SM0. If the differential read signal is sufficiently large then step 4 is performed.
4. Write data to and then read data from the memory cell with the time window of the transistors 813 or 815 set to an even larger value corresponding to second signal margin (SM2) to drain more of the charge from the bit-lines. If the differential read signal is too small, then a comparison of the read data with the write data fails, thereby indicating that the circuit has a signal margin corresponding to SM1. If the differential read signal is sufficiently large then the test is continued until the failure of the comparison.

In another embodiment, the above procedure is performed by increasing the charge on the bit-line having the lower bit-line voltage level rather than, or in addition to, decreasing the charge on the bit-line having the higher bit-line voltage level.

In another embodiment of the invention, each of the additional resistors (RSM) 801 or 803 can be divided into more than one part, in order to realize a variety of signal margin steps. Thus, rather than changing the time window (tON-tOFF), the amount of charge discharged from the bit-lines can be varied by changing the value of resistance attached to the transistors TSM 813 or 815.

Alternatively, a combination of changing the time window and resistances can be used to vary the amount the bit-lines are discharged.

The embodiment illustrated in FIG. 9 is similar to that of FIG. 8, except that the resistors (RSM) 803 and 805 are not coupled to ground, but rather to the potentials P 903 and Pr 905, respectively. The potentials 903 and 905 can be static or pulsed. The circuit of this embodiment gives more freedom to chose the signal margin. Thus, in addition to changing the time window and changing the resistances 803, 805, the charge on the bit-lines 103, 107 can be changed by using different potentials P 903 and/or Pr 905 in the above described procedure to test for the analog value of the signal margin.

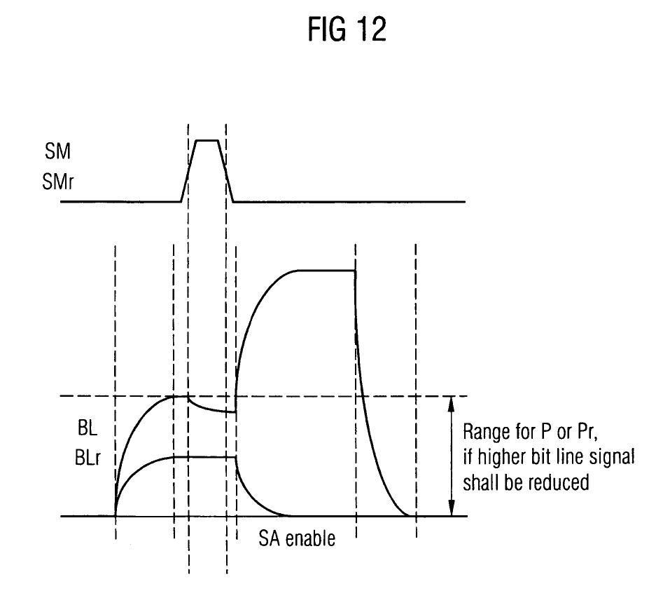

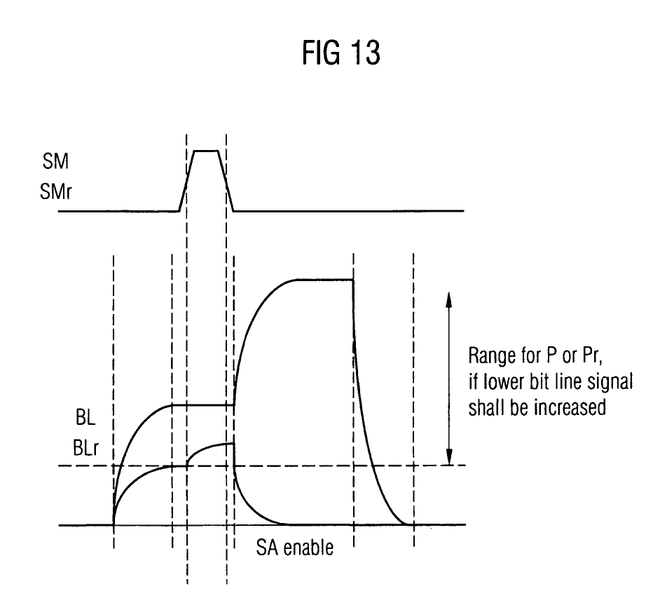

FIG. 12 illustrates the situation wherein the potential P 903 or Pr 905 is in the range between ground and the higher original bit-line voltage level, and it is connected via a resistor and transistor to the bit-line with the higher voltage. The potential P 903 or Pr 905 is thus used to decrease the higher bit-line voltage level. The magnitude of the bit-line voltage decrease depends on the potential P 903 or Pr 905. FIG. 13 illustrates the situation wherein the potential P 903 or Pr 905 is higher than the lower original bit-line voltage, and it is connected via a resistor and transistor to the bit-line with the lower voltage. The potential P 903 or Pr 905 is thus used to increase the lower bit-line voltage level. The magnitude of the bit-line voltage increase depends on the potential P 903 or Pr 905.

### Third Embodiment

### Defined Charge Exchange

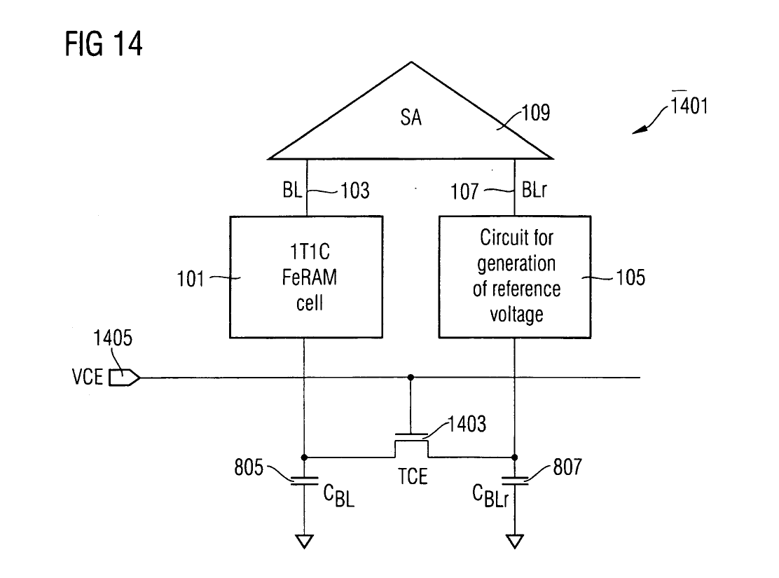

FIG. 14 shows a circuit schematic of a memory chip circuit 1401 according to an embodiment of the invention. The circuit of FIG. 14 differs from the prior art circuit of FIG. 1 in that a transistor TCE 1403 connects bit-line BL 103 with bit-line BLr 107 and thus allows for the exchange of charge between the bit-line capacitors CBL 805, CBLr 807.

The transistor is activated at it's gate by a signal input VCE 1405. The signal input VCE 1405 is kept at non-active (wherein the transistor TCE 1403 is off) during normal operation and the circuit is electrically similar to the circuit shown in FIG. 1. During testing, the signal VCE 1405 can be activated thereby transferring charge between the bit-lines BL 103 and BLr 107.

The memory chip circuit 1401 of FIG. 14 provides a test mode circuit for testing for signal margin. In order to test the memory chip circuit 1401, data is first written into the memory cell 101 and afterwards the data is read and compared to the expected (i.e. written) data. The signal margin can be tested by selectively reducing the difference between a “0” signal on one bit-line and a “1” signal on the other bit-line. This is achieved by the present embodiment in a way that a defined charge exchange is performed between the bit-lines BL 103 and BLr 107 after the read signals have developed. In one implementation, the transistor TCE 1403 connects BL 103 and BLr 107 as illustrated in FIG. 14. By adjusting the control signal VCE 1405 (gate-source voltage) and the time the gate is opened, a defined amount of charge is allowed to flow from the bit-line with the “1,” signal to the bit-line with the “0” signal, thereby reducing the “1” and increasing the “0” simultaneously.

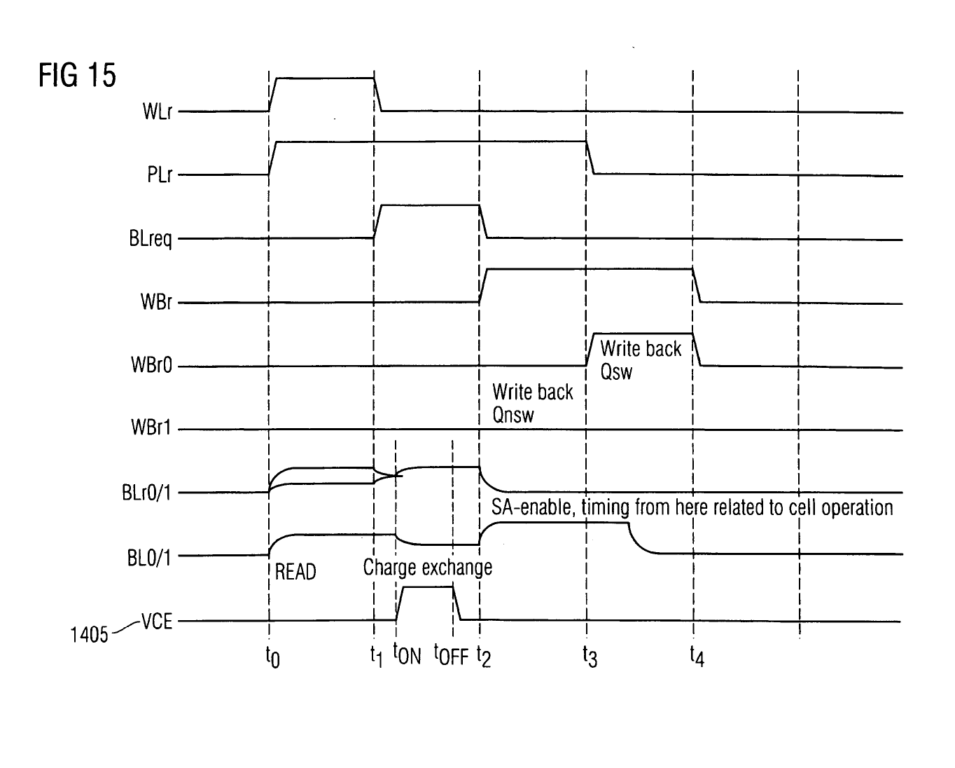

FIG. 15 shows the reference bit-line signals for the case where the potential of the bit-line BL 103 is expected to have a signal level higher than the reference bit-line BLr 107. The steps t0 to tON are performed as in FIG. 4. The test mode of the present invention is activated at time tON by applying a test mode signal potential VCE 1405 (see FIG. 14) to the gate of a transistor TCE 1403. The potential VCE 1405 activates the transistor TCE 1403 to transfer charge from the bit-line BL 103 to the reference bit-line BLr 107 to lower the voltage on the bit-line BL 103 and raise the voltage on the reference bit-line BLr 107 as shown by the plots of the potential of BL0/1 and BLr0/1 from tON to tOFF in FIG. 15.

After the transferring the charge from the bit-line BL 103 to the reference bit-line BLr 107, the potential VCE 1405 is turned off at time tOFF and the remaining operations are performed as in FIG. 4. In this example the pre-charging is shown during the time interval tON to tOFF, however, as in the previous examples, the precharging can be performed during other time intervals between t0 and activation of the sense amplifier 109 at t2.

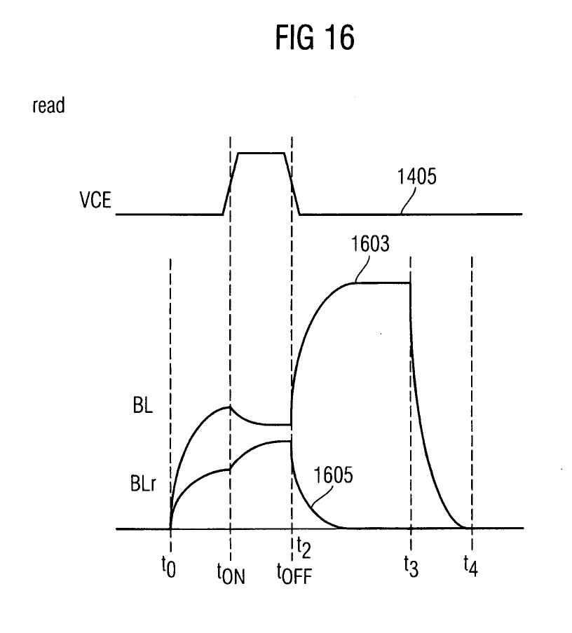

FIG. 16 shows the signals on the bit-line BL 103 and reference bit-line BLr 107 in greater detail. The signal VCE 1405 is shown for activating the transistor TCE 1403. The traces 1603 and 1605 represent the signal levels on the bit-lines BLr 107 and BL 103, respectively. In this example, the bit-line BLr 107 is assumed to be the bit-line with the lower read signal. The bit-lines BL 103 and BLr 107 are pre-charged to a certain level (e.g. 0V in the figure) and at time t0 the reference plate PLr and the word line WLr are activated and a read signal appears on the bit-lines. At time tON the signal VCE 1405 is activated switching on the transistor TCE 1403 and opening up a charge transfer path between the bit-lines BL 103 and BLr 107. The signal VCE 1405 can be, in general, activated during the time after signal development on the bit-lines (soon after activation of the reference plate PLr and the word line WLr) and can be deactivated just before sense amplifier 109 activation. However, there is no limitation on the activation period for the signal VCE 1405. The activation period of the signal VCE 2405 and the corresponding on-time of the transistor TCE 1403 should at least partially overlap the period of time between activation of the reference plate PLr and the word line WLr at time t0 and the sense amplifier 109 activation time t2. The charge on the bit-line with the higher read signal is decreased while the charge on the bit-line with the lower read signal is increased resulting in a decreased signal on this bit-lines at t2 when a sense amplifier 109 is activated and the bit-line signals are boosted to the full bit-line 10 voltages. As a result, the differential read signal, i.e. the difference between the two bit-line signals, is decreased accordingly, which tightens the margin for a save operation of the chip (the worst case test condition). At t3 the sense amplifier is deactivated and the access cycle ends at t4.

The effect of this test mode is that after signal development on the bit-lines (following the activation of the reference common plate line PLr and reference word line WLr, and just before sense amplifier 109 activation) the difference between the “0” signal on the bit-line BLr 107 (see FIG. 14) and the “1” signal on the bit-line BL 103 (again, see FIG. 14) is smaller than in the normal read operation. The result of this test mode is a reduced differential read signal (i.e. the difference between the two bit-line signals) which tightens. the margin for a save operation of the chip (the worst case test condition). The amount of “signal margin” can be controlled by the time window during which the transistor TCE 1403 is switched on.

One example of the procedure to test for the analog value of the signal margin is illustrated by the following steps:
1. Write data to and then read data from the memory cell in normal operation (without activating the transistor TSM 1403). If the differential read signal is too small, then a comparison of the read data with the write data fails, thereby indicating that the circuit has no signal margin. If the differential read signal is sufficiently large then step 2 is performed.
2. Write data to and then read data from the memory cell with the time window of the transistor 1403 set to a small value signal margin (SM0) to drain some of the charge from the bit-lines. If the differential read signal is too small, then a comparison of the read data with the write data fails, thereby indicating that the circuit has no signal margin. If the differential read signal is sufficiently large then step 3 is performed.
3. Write data to and then read data from the memory cell with the time window of the transistor 1403 set to a slightly larger value corresponding to first signal margin (SM1) to drain some of the charge from the bit-lines. If the differential read signal is too small, then a comparison of the read data with the write data fails, thereby indicating that the circuit has a signal margin corresponding to SM0. If the differential read signal is sufficiently large then step 4 is performed.
4. Write data to and then read data from the memory cell with the time window of the transistor 1403 set to an even larger value corresponding to second signal margin (SM2) to drain more of the charge from the bit-lines. If the differential read signal is too small, then a comparison of the read data with the write data fails, thereby indicating that the circuit has a signal margin corresponding to SM1. If the differential read signal is sufficiently large then the test is continued until the failure of the comparison.

In another alternative embodiment, a more sophisticated constant current sink/source is implemented instead of a transistor TCE, providing more accurate control of the amount of charge that is exchanged between BL and BLr.

### Fourth Embodiment

### Defined Charge and Discharge of BL and BLr

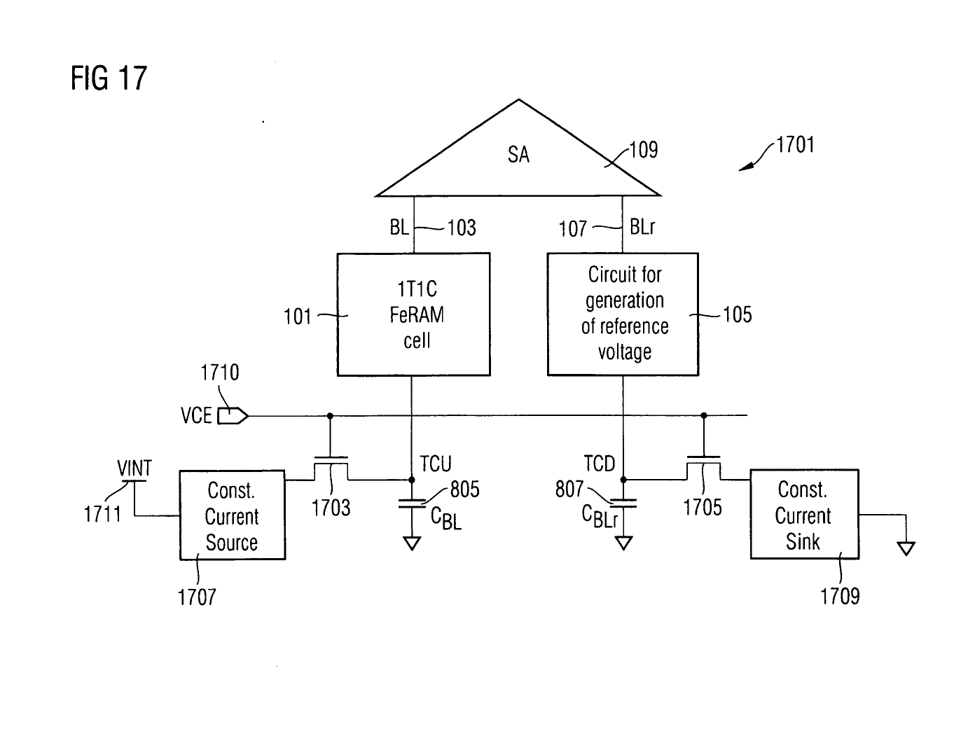

FIG. 17 shows a circuit schematic of a memory cell 10 according to the invention. A constant current source 1707 is connected in parallel to the bit-line capacitance 805 and a constant current sink 1709 is connected in parallel to the reference bit-line capacitance 807. The constant current source 1707 and the constant current sink 1709 are switchable for the bit-line BL 103 and reference bit-line BLr 107 by the signal VCE 1710 on transistors TCU 805 and TCD 807. In another embodiment, only one of the constant current source 1707 or the constant current sink 1709 is activated. The signal input VCE 1710 is kept at non-active (wherein the transistors 1703 and 1705 are off) during normal operation and the circuit is electrically similar to the circuit shown in FIG. 1. During testing, the signal input VCE 1710 can be activated thereby opening a controlled path for charge via the constant current source 1707 and the constant current sink 1709, thus decreasing the read voltage on the respective bit-lines. The higher signal, which can be on the bit-line BL 103 or the reference bit-line BLr 107, is reduced by a constant current sink and the lower signal, which can be on the bit-line BL 103 or the reference bit-line BLr 107, is increased by a constant current source and the difference between the higher and lower bit-line signals becomes smaller for this test. The amount of “signal margin” can be controlled by the time window, during which the transistor TSM 24 is switched on, i.e. between tMon and tMoff.

In order to test the memory cell of FIG. 17, data is first written into the memory cell and afterwards the data is read and compared to the expected (i.e. written ) data. Thus, during testing it is known which line, BL 103 or BLr 107, should have a lower and which should have a higher signal. The signal margin can be tested by selectively reducing the difference between a “0” signal on one bit-line and a “1” signal on the other bit-line. In the embodiment of FIG. 17, a well defined charge of BL 103 and a discharge of BLr 107 is performed after the read signals have developed. A constant current sink 1709 connects the reference bit-line BL 107 with ground via a transistor TCD 1705, and a constant current source 1707 connects the bit-line BL 103 with the supply voltage VINT 1711 via the transistor TCU 1703 (see FIG. 17). When the control signal VCE 1710 is activated, a defined amount of charge is taken away from or added to BL 103 and BLr 107, respectively. This charge amount is defined by the current flow (constant) and the time VCE is active, i.e., it is linearly dependent on time and, therefore, well controllable.

The effect of this test mode is that after signal development on the bit-lines (following the activation of the reference common plate PLr and reference word line WLr, and just before sense amplifier 109 activation, see FIG. 3) the difference between the “0” signal on the bit-line BL 103 and the “1” signal on the reference bit-line BLr 107 is smaller than in the normal read operation. The result of this test mode is a reduced differential read signal (i.e. the difference between the two bit-line signals) which tightens the margin for a save operation of the chip (the worst case test condition).

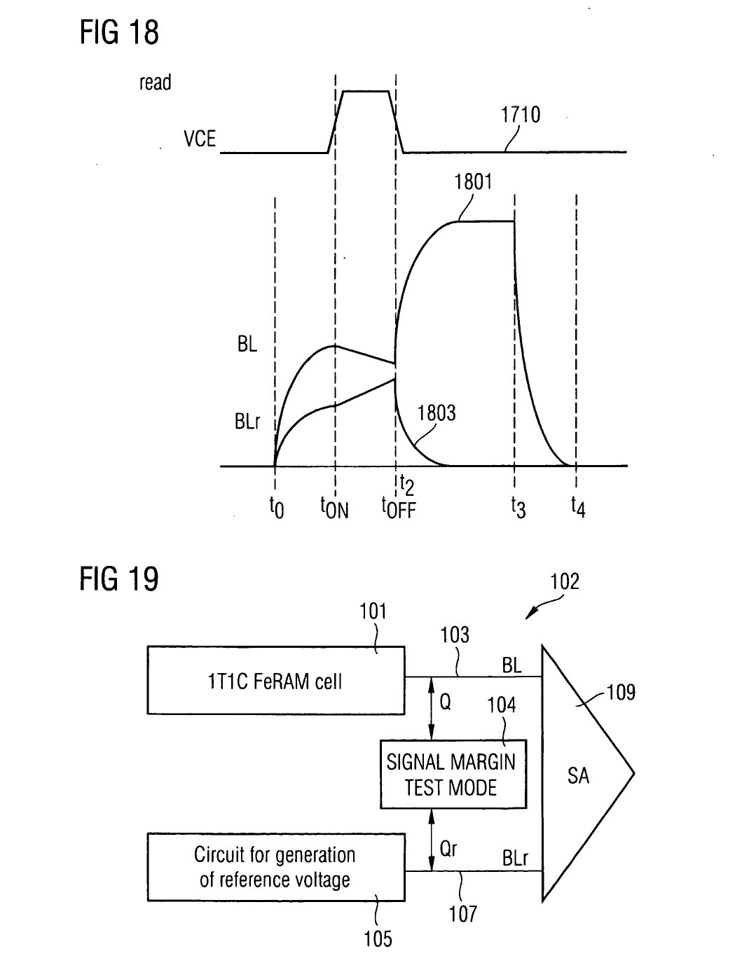

In the example of FIG. 18, the bit-line BL 103 is assumed to be the bit-line with the lower read signal. The bit-line BL 103 and the reference bit-line BLr 107 are pre-charged to a certain level (e.g. 0V in the figure) and at time t0 the reference common plate PLr and reference word line WLr are activated and a read signal appears on the bit-lines. At time tON the full read signals are developed on the two bit-lines 103, 107. The signal VCE 30 is activated switching on the transistors TCD 1705 and TCU 1703 for removing charge from and adding charge to the bit-lines BLr 107 and BL 103′, respectively. The signal VCE 1710 can be, in general, activated during the time after signal development on the bit-lines (soon after the activation of the reference common plate PLr and reference word line WLr) and can be deactivated just before the sense amplifier 109 activation. However, there is no limitation on the activation period for the signal VCE 1710. The activation period of the signal VCE 1710 and the corresponding on-time of the transistors TCD 1705 and TCU 1703 should at least partially overlap the period of time between activation of the reference common plate PLr and reference word line WLr at time tON and the sense amplifier 109 activation time t2 (tOFF). The charge on the bit-line with the higher read signal is decreased while the charge on the bit-line with the lower read signal is increased resulting in a decreased signal on this bit-lines at t2 when the sense amplifier 109 is activated and the bit-line signals are boosted to the full bit-line voltages. As a result, the differential read signal, i.e. the difference between the two bit-line signals, is decreased accordingly, which tightens the margin for a save operation of the chip (the worst case test condition). At t3 the sense amplifier is deactivated and the access cycle ends at t4.

One example of the procedure to test for the analog value of the signal margin is illustrated by the following steps:
1. Write data to and then read data from the memory cell in normal operation (without activating the transistors TCU 805 and TCD 807). If the differential read signal is too small, then a comparison of the read data with the write data fails, thereby indicating that the circuit has no signal margin. If the differential read signal is sufficiently large then step 2 is performed.
2. Write data to and then read data from the memory cell with the time window of the transistors 805 and/or 807 set to a small value signal margin (SM0) to drain some of the charge from or add charge to the bit-lines. If the differential read signal is too small, then a comparison of the read data with the write data fails, thereby indicating that the circuit has no signal margin. If the differential read signal is sufficiently large then step 3 is performed.
3. Write data to and then read data from the memory cell with the time window of the transistors 805 and/or 807 set to a slightly larger value corresponding to first signal margin (SM1) to drain some of the charge from or add charge to the bit-lines. If the differential read signal is too small, then a comparison of the read data with the write data fails, thereby indicating that the circuit has a signal margin corresponding to SM0. If the differential read signal is sufficiently large then step 4 is performed.
4. Write data to and then read data from the memory cell with the time window of the transistors 805 and/or 807 set to an even larger value corresponding to second signal margin (SM2) to drain more of the charge from or add charge to the bit-lines. If the differential read signal is too small, then a comparison of the read data with the write data fails, thereby indicating that the circuit has a signal margin corresponding to SM1. If the differential read signal is sufficiently large then the test is continued until the failure of the comparison.

The control signal VCE 1710 can be separated into VCED for turning on the transistor TCD 1705 and into VCEU for turning on the transistor TCU 1707. By doing so, charging of BL and discharging of BLr can be performed separately. Alternately, the only a constant current source or a constant current sink, without using the other one, can be used to reduce the differential read signal.

In alternative embodiments, the potentials used to supply the transistors of the test mode section are generated chip internally (on the same chip) or are provided externally.

As mentioned above, there are no limitations for tON and tOFF for the present invention. The pre-charging and/or pre-draining of charge can be performed during other time intervals prior to or even after activation of the sense amplifier 109 at t4.

In all of the above embodiments the described components, including the resistors and the transistors can be formed on the same die. Also, the term “connected” as used in the present disclosure does not imply that connected components must be in direct physical contact. Rather, the components need only be electrically connected.

Thus, although the invention has been described above using particular embodiments, many variations are possible within the scope of the claims, as will be clear to a skilled reader.

1. A semiconductor memory test mode configuration, comprising:
a first capacitor for storing digital data connecting a cell plate line to a first bit-line through a first select transistor, the first select transistor activated through a connection to a word line;
at least one reference capacitor for providing a reference voltage to a reference bit-line;
a sense amplifier connected to the first and reference bit-lines for measuring a differential read signal on the first and reference bit-lines; and
a charge path for reducing the differential read signal to determine the signal margin of the semiconductor memory.

2. The semiconductor memory test mode configuration of claim 1, wherein, after a write of “0” data and read thereof, the first bit-line has a lower signal than the reference bit-line and the charge path increases the charge on the first bit-line.

3. The semiconductor memory test mode configuration of claim 1, wherein the reference bit-line has a lower signal than the first bit-line and the charge path increases the charge on the reference bit-line.

4. The semiconductor memory test mode configuration of claim 1, wherein the first bit-line has a higher signal than the reference bit-line and the charge path decreases the charge on the first bit-line.

5. The semiconductor memory test mode configuration of claim 1, wherein the reference bit-line has a higher signal than the first bit-line and the charge path decreases the charge on the reference bit-line.

6. The semiconductor memory test mode configuration of claim 1, wherein reference bit-line has a higher signal than the first bit-line and the charge path both decreases the charge on the reference bit-line and increases the charge on the reference bit-line.

7. The semiconductor memory test mode configuration of claim 1, wherein reference bit-line has a lower signal than the first bit-line and the charge path both increases the charge on the reference bit-line and decreases the charge on the reference bit-line.

8. The semiconductor memory test mode configuration of claim 1, wherein the charge transfer path includes a third transistor turned on and off to reduce the differential read signal.

8. The semiconductor memory test mode of claim 1, wherein the first and reference capacitors are ferroelectric capacitors.

9. The semiconductor memory test mode of claim 1, wherein the first capacitor is part of an FeRAM.

10. A method for testing the signal margin of a semiconductor memory comprising the steps of:
reducing the difference between the amount of charge on a reference bit-line having a voltage supplied by a reference capacitor and on a first bit-line having a voltage provided by an external voltage;
activating a sense amplifier connected to the first and reference bit-lines thereby boosting read signals on the first bit-line representing digital data read from a capacitor and boosting read signals on the reference bit-line; and
determining a reduced differential read signal on the first and reference bit-lines due to the changed amount of charge on the bit-lines.

11. The method of claim 10 wherein the charges on the reference bit-line and the first bit-line are supplied by ferroelectric capacitors.

12. The method of claim 10, wherein the capacitor is part of an FeRAM.

13. The method of claim 10, wherein reducing the difference between the amount of charge on a reference bit-line and on a first bit-line comprises increasing the charge on the first bit-line.

14. The method of claim 10, wherein reducing the difference between the amount of charge on a reference bit-line and on a first bit-line comprises increasing the charge on the reference bit-line.

15. The method of claim 10, wherein reducing the difference between the amount of charge on a reference bit-line and on a first bit-line comprises decreasing the charge on the first bit-line.

16. The method of claim 10, wherein reducing the difference between the amount of charge on a reference bit-line and on a first bit-line comprises decreasing the charge on the reference bit-line.

17. The method of claim 10, wherein reducing the difference between the amount of charge on a reference bit-line and on a first bit-line comprises both decreasing the charge on the reference bit-line and increasing the charge on the reference bit-line.

18. The method of claim 10, wherein reducing the difference between the amount of charge on a reference bit-line and on a first bit-line comprises both increasing the charge on the reference bit-line and decreasing the charge on the reference bit-line.
